(19) United States
(12) Patent Application Publication
(10) Pub. No.: US 2021/0202318 A1
(43) Pub. Date: Jul. 1, 2021

(54) METHODS OF FORMING SEMICONDUCTOR DIES WITH PERIMETER PROFILES FOR STACKED DIE PACKAGES

(71) Applicant: Micron Technology, Inc., Boise, ID (US)

(72) Inventors: Yeongbeom Ko, Taichung (TW); Jong Sik Paek, Taichung (TW)

(21) Appl. No.: 16/896,091

(22) Filed: Jun. 8, 2020

Related U.S. Application Data
(60) Provisional application No. 62/954,254, filed on Dec. 27, 2019.
(60) Provisional application No. 62/954,263, filed on Dec. 27, 2019.

(51) Int. Cl. H01L 21/78; H01L 21/268

(52) U.S. Cl. CPC H01L 21/78; H01L 21/268

(57) ABSTRACT

The present technology is directed to methods of forming semiconductor dies with rabbeted regions. For example, the method can comprise forming a first channel along a street from a backside of the wafer to an intermediate depth between the backside of the wafer and a front side of the wafer. The first channel has a first sloped sidewall and a second sloped sidewall. A second channel is then formed by laser cutting from the intermediate depth in the wafer toward the front side of the wafer along a region between the first and second sidewalls of the first channel. The first sloped sidewall defines a rabbeted region at a side of the first semiconductor dies and the second sloped sidewall defines a rabbeted region at a side of the second semiconductor dies.

### CROSS-REFERENCE TO RELATED APPLICATIONS

This application claims the benefit of U.S. Provisional Application Nos. 62/954,254, filed Dec. 27, 2019 and titled “METHODS OF FORMING SEMICONDUCTOR DIES WITH PERIMETER PROFILES FOR STACKED DIE PACKAGES”; and 62/954,263, filed Dec. 27, 2019 and titled “SEMICONDUCTOR DEVICE ASSEMBLIES INCLUDING STACKED SEMICONDUCTOR DIES”; each of which is incorporated herein by reference in its entirety and made a part of the present disclosure.

### TECHNICAL FIELD

The present technology is directed toward methods for forming semiconductor dies with perimeter profiles for stacked die packages, and in particular semiconductor dies having a rabbeted region along at least a portion of the perimeter.

### BACKGROUND

Packaged semiconductor dies, including memory chips, microprocessor chips, and imager chips, typically include one or more semiconductor dies mounted on a substrate and encased in a plastic protective covering or covered by a heat-conducting lid. The die can include active circuits that provide functional features, such as memory cells, processor circuits, and/or imager devices. The die can also or alternatively include passive features such as capacitors, resistors, and the like. The die can also include bond pads electrically coupled to the active circuits and external terminals outside the protective covering for connecting to higher level circuitry.

To provide additional functionality additional semiconductor dies can be added to a semiconductor device assembly by stacking the dies on each other. FIG. 1 illustrates a semiconductor device assembly 100 in which spacer tape 105 and/or other materials are used to space dies 104 from each other to provide access to bond pads 108 (e.g., contact pads) on the dies 104. The spacer tape 105 has a smaller width W1 than the width W2 of the dies 104 such that wirebonds 121 can be formed between the bond pads 108 and bonding sites 120 on the substrate 101. As illustrated, the spacer tape 105 adds to the height H1 for one or more of the semiconductor dies 104.

To reduce the vertical space required for wirebonds, the dies can be arranged in shingled stacks in which each die is offset horizontally from a die below to expose the bond pads of each die for wirebonding. Shingled stacking, however, can limit on the number of dies that can be stacked in this fashion because the overhang of each sequential die in the stack increases the overall footprint of the die stack.

Such shingled stacks of dies can include multiple groups of dies in a shingled arrangement that are offset either in the same direction (FIG. 2) or in opposing directions (FIG. 3). FIG. 2 illustrates a semiconductor device assembly 200 in which a shingled stack 210 of dies on a substrate 201 includes two die groups 202 and 203 of dies 204 which are shingled in the same offset direction and wirebonded to bonding sites 220 on the substrate 201. As shown in FIG. 2, the wirebonds 221 of the first die group 202 are underneath an overhang region 211 of the second die group 203, and therefore these wirebonds 221 must be formed before the second die group 203 is stacked over the first die group 202. Moreover, the bottommost die 204 of the second die group 203 must be spaced above the topmost die 204 of the first die group 202 by a sufficient distance to allow space for forming a wirebond 221 thereto. Accordingly, drawbacks of this arrangement include having a large footprint occupied by the shingled stack(s) of individual dies 204.

Referring to FIG. 3, similar challenges are presented in forming the semiconductor device assembly illustrated 300 in which the die groups are shingled in opposing offset directions. The semiconductor device assembly 300 has a shingled stack 310 of dies 304 on a substrate 301 with two die groups 302 and 303 shingled in opposing offset directions and wirebonded to bonding sites 320 on the substrate 301. At least some of the wirebonds 321 of the first die group 302 of dies 304 are underneath an overhang region 311 of the second die group 303, and therefore these wirebonds 321 must be formed before the second die group 303 is stacked over the first die group 302. Accordingly, drawbacks of this arrangement also include having a large footprint occupied by the shingled stack(s) of individual dies 304.

### BRIEF DESCRIPTION OF THE DRAWINGS

FIG. 1 illustrates a semiconductor device assembly in the prior art including a stack of semiconductor dies spaced apart by spacer tape.

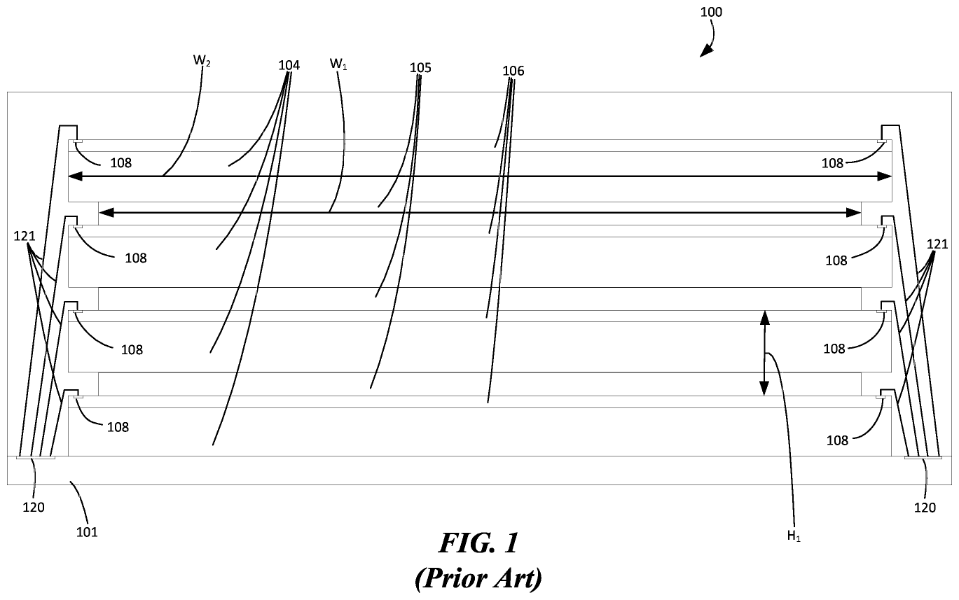

FIG. 2 illustrates a semiconductor device assembly in the prior art including a shingled stack of semiconductor dies in one configuration.

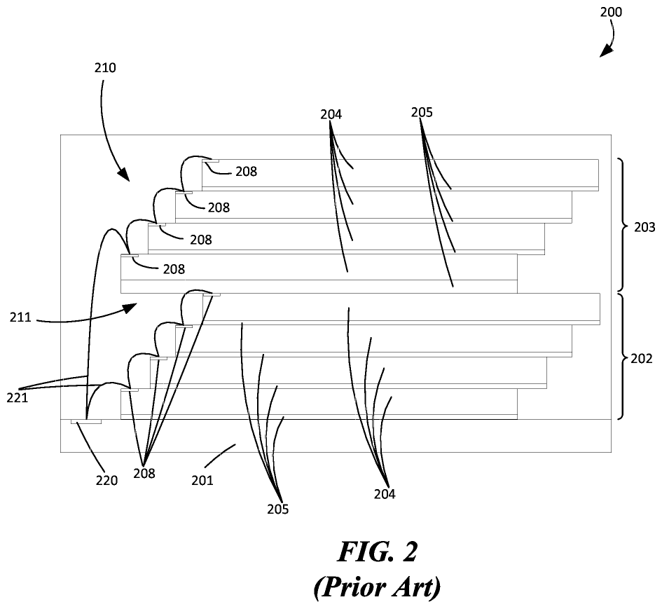

FIG. 3 illustrates a semiconductor device assembly in the prior art including a shingled stack of semiconductor dies in another configuration.

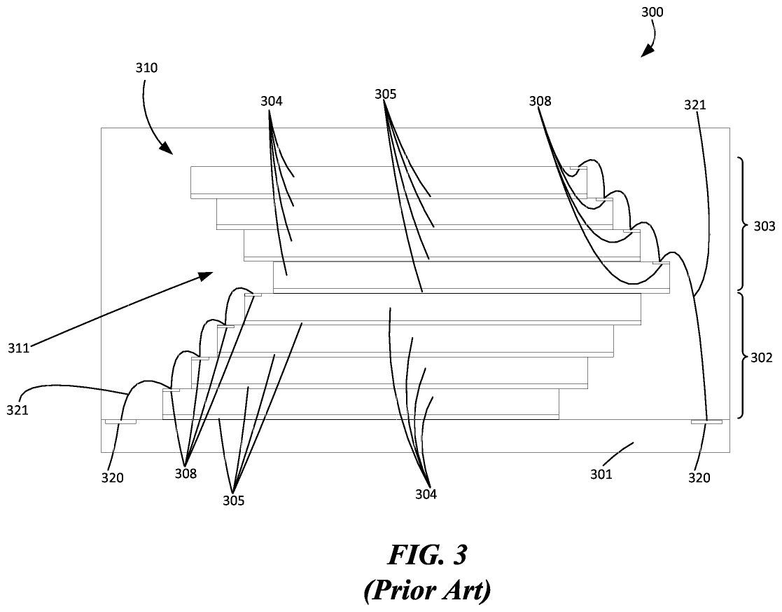

FIG. 4 is a schematic top view of a semiconductor wafer that may be processed in accordance with the present technology to form semiconductor devices with rabbeted regions.

FIG. 5 is an enlarged view of the encircled portion of FIG. 4.

FIGS. 6A-6D are schematic cross-sectional views illustrating aspects of a method of forming semiconductor devices with rabbeted regions in accordance with the present technology.

FIG. 7 is a schematic cross-sectional view illustrating aspects of a method of forming semiconductor devices with rabbeted regions in accordance with the present technology.

FIG. 8 is a schematic view showing a system that includes a semiconductor device assembly configured in accordance with an embodiment of the present technology.

### DETAILED DESCRIPTION

As discussed above, increasing the number of semiconductor dies in a stack of a semiconductor device assembly poses manufacturing challenges. For example, multiple iterative stacking and wirebonding operations, varying die-to-die spacing, and extensive height are among some of the manufacturing challenges. Accordingly, several embodiments of the present technology are directed to methods of manufacturing semiconductor devices with perimeter profiles designed to overcome these challenges.

For example, a method in accordance with the present technology includes forming a first channel along a street from a backside of the wafer to an intermediate depth between the backside of the wafer and a front side of the wafer. The first channel can have a first sloped sidewall and a second sloped sidewall that converge toward each other from the backside toward the intermediate depth. The method also includes forming a second channel by laser cutting from the intermediate depth in the wafer toward the front side of the wafer along an interface region where the first and second sidewalls of the first channel meet. The second channel separates a set of first semiconductor dies along the first sidewall from a set of second semiconductor dies along the second sidewall. The first sloped sidewall defines a rabbeted region at a side of the first semiconductor dies and the second sloped sidewall defines a rabbeted region at a side of the second semiconductor dies.

Another method in accordance with the present technology includes cutting a channel along a street from a backside of a wafer to an intermediate depth between the backside of the wafer and a front side of the wafer. The channel can have first and second sloped sidewalls that converge toward each from the backside toward the intermediate depth. The method also includes separating a set of first dies along the first sloped sidewall from a set of second dies along the second sloped sidewall by laser cutting along a midline of the channel to form a kerf from the intermediate depth to the front side of the wafer. The first sloped sidewall defines a rabbeted region along a side of the first dies and the second sloped sidewall defines a rabbeted region along a side of the second dies.

The term “semiconductor device” generally refers to a solid-state device that includes one or more semiconductor materials. Examples of semiconductor devices include logic devices, memory devices, diodes, and other devices with semiconductor materials. Furthermore, the term “semiconductor device” can refer to a finished device or assembly, or other structures at various stages of processing before becoming a finished device. In some embodiments, an individual semiconductor device may be “packaged” and include a molding material encasing the components and electrical connections in the device.

Depending upon the context in which it is used, the term “substrate” can refer to a structure that supports electronic components (e.g., a die), such as a wafer-level substrate or a singulated, die-level substrate. The term substrate can also mean another die for die-stacking applications. The methods described herein are generally performed at the wafer-level, but they can also be performed at the die level.

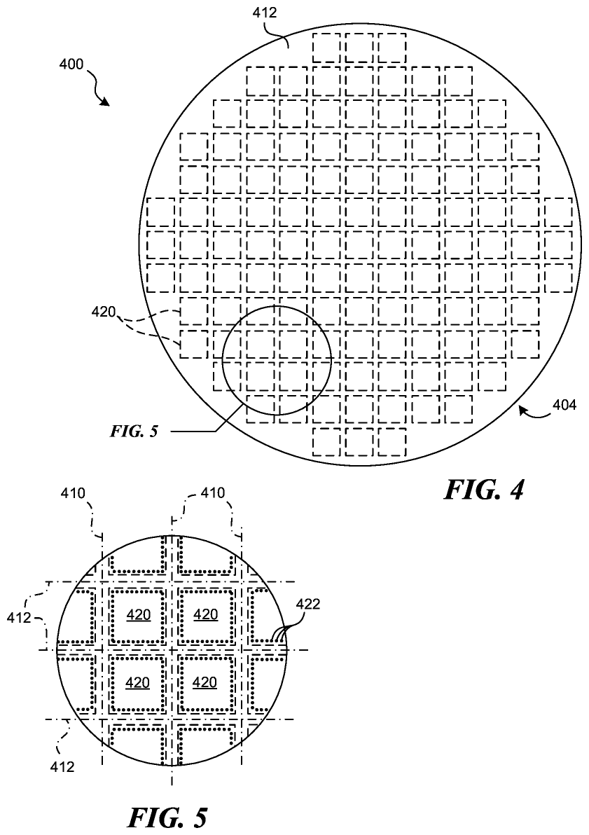

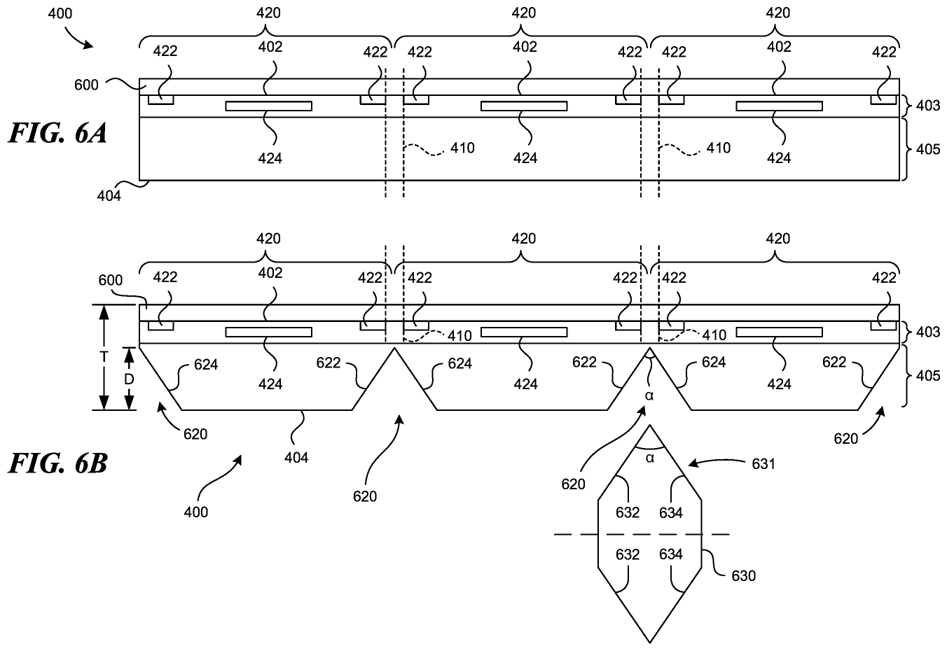

FIGS. 4 and 5 illustrate a semiconductor wafer 400 (“wafer 400”) that may be processed in accordance with the present technology to produce semiconductor dies with a rabbeted region along at least a portion of a side (e.g., an edge) of a semiconductor die. The wafer 400 has a front side 402 and a backside 404 opposite the front side 402, and the backside 404 is spaced apart from the front side 402 by a wafer thickness. The wafer 400 has semiconductor dies 420 arranged in an array at the front side 402. The spaces between semiconductor dies 420 define a set of generally parallel first “streets” 410 (FIG. 5) in one direction and a set of generally parallel second “streets” 412 (FIG. 5) in another direction. The first and second streets 410, 412 can be orthogonal to each other as shown in FIGS. 4 and 5, but the streets are not limited to an orthogonal arrangement. Referring to FIG. 5, each of the semiconductor dies 420 may include an array of contacts 422 at the front side 402 of the wafer 400.

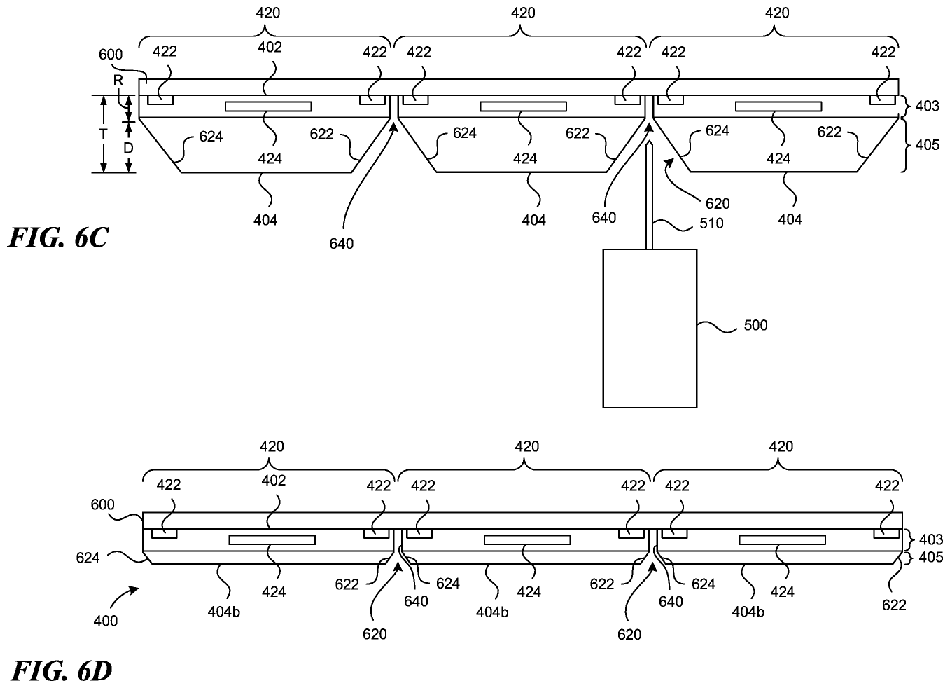

FIGS. 6A-6D show aspects of processing a portion of the semiconductor wafer 400 (e.g., three of the semiconductor dies 420) for producing semiconductor dies with a rabbeted region in accordance with the present technology. It will be appreciated that the process can be implemented across the full length of the streets of a wafer. Referring to FIG. 6A, the wafer 400 has an active region 403 at the front side 402 and an inactive region 405 between the active region 403 and the backside 404. Each of the semiconductor dies 420 has integrated circuitry 424 and contacts 422 at the active region 403 that are electrically coupled to the integrated circuitry 424. At this stage of the process, a wafer carrier 600 is attached to the active region 403 at the front side 402. The wafer carrier 600 can be a carrier tape such as a back-grinding tape or another suitable laminate that can be attached to the front side 402 to protect the contacts 422 and the integrated circuitry 424 during processing.

FIG. 6B illustrates the wafer 400 after first channels 620 have been formed along the streets 410 from the backside 404 of the wafer 400 to an intermediate depth D within the wafer 400 that is less than the full thickness T of the wafer 400. The intermediate depth D is between the backside 404 and the front side 402 of the wafer 400. The intermediate depth D can be within the inactive region 405 but not within the active region 403 of the wafer 400. In other embodiments, the intermediate depth D can extend into the active region 403. The first channels 620 have a first sloped sidewall 622 and a second sloped sidewall 624 that converge toward each other from the backside 404 of the wafer 400 toward the intermediate depth D within the wafer 400. In the embodiment shown in FIGS. 6B-6D, the first and second sloped sidewalls 622 and 624 are first and second beveled surfaces, respectively, at an angle a with respect to each other such that the first channels 620 have a V-shape. The first and second beveled surfaces of the first channels 620 can be formed by cutting the first channels 620 with a dicing blade 630 having a cutting edge 631 with beveled surfaces 632 and 634 that are at the angle a with respect to each other. The maximum widths of the respective first channels 620 are preferably greater than the widths of the streets 410, as measured parallel to the faces of the active region 403.

FIG. 6C illustrates the wafer 400 after second channels 640 have been formed from the intermediated depth D to the front side 402 of the wafer 400. Each second channel 640 is formed in an interface region where the first and second sidewalls 622 and 624 of the first channel 620 meet. The interface region is generally aligned with a street 410 (FIG. 6B). The second channels 640 can extend through the full remaining thickness R of the wafer 400 such that the second channels 640 pass completely through the active region 403 to separate the semiconductor dies 420 from each other. The second channels 640, however, do not need to extend through the full thickness of the active region 403, but rather they can rather extend through a sufficient portion of the active region 403 so that the semiconductor dies 420 can be separated from each other by flexing the wafer carrier 600 such that the wafer 400 cracks along the second channels 640. In a typical application, several semiconductor dies 420 are along each street 410 such that each second channel 640 separates a set of first semiconductor dies along the first sidewall 622 of a corresponding first channel 620 from a set of second semiconductor dies along the second sidewall 624 of the corresponding first channel 620. Preferably, the widths of the respective second channels 640 are less than or equal to the widths of the streets 410. The first sidewall 622 accordingly defines a rabbeted region along a side of the first semiconductor dies, and the second sloped sidewall 624 accordingly defines a rabbeted region along a side of the second semiconductor dies. These rabbeted regions end at the boundaries of the second channels 640 in the illustrated embodiments.

The second semiconductor channels 640 are formed using a laser 500 that directs a laser beam 510 to the interface region between the first and second sloped sidewalls 622 and 624 of the corresponding first channel 620. Since the first channels 620 remove at least a substantial portion of the inactive region 405 of the wafer 400, a single pass of the laser beam 510 may form the second channels completely through the remaining thickness R of the wafer 400. The present technology, however, also includes forming the second channels 640 using multiple passes of the laser beam 510. The second semiconductor channels 640 can be a kerf having a width K that separates the semiconductor dies 420 from each other without impacting the contacts 422. The kerf width K can be approximately 10-20 μm, and in many applications it can be 15 μm. In some embodiments, the dicing blade 630 includes a second cutting portion extending beyond the beveled surfaces 632, 634 at an angle smaller than the angle a of the beveled surfaces 632, 634. This second cutting portion can be configured to cut the second channel 640 during the same operation used to cut the first channel 620.

FIG. 6D illustrates the wafer 400 after the inactive region 405 has been thinned to reduce the overall thickness of the individual semiconductor dies 420. For example, the wafer 400 can be thinned by back grinding the wafer 400 from the elevation of the backside 404 shown in FIG. 6C to the elevation of the backside 404a shown in FIG. 6D. After the wafer 400 has been thinned, the thinned backside 404a can be attached to a mounting tape and the wafer carrier 600 can be removed from the front side 402 of the wafer. The semiconductor dies 420 now include one or more rabbeted regions along at least a portion of a side or edge.

The method described above with reference to FIGS. 6A-6D advantageously produces semiconductor dies with rabbeted regions for accommodating wirebonds in a stacked die arrangement. Instead of cutting the first and second channels with two different saw blades, the present technology can quickly form the rabbeted regions using a single saw blade and a laser to achieve a narrow kerf width between adjacent semiconductor dies 420. Additionally, the front side 402 of each semiconductor die 420 is protected by the wafer carrier 600 throughout the process, which reduces contamination of the front side and damage during handling. Another advantage of at least some embodiments of the method described above with reference to FIGS. 6A-6D is that the first and second channels 620 and 640 can be formed with a single pass of a saw blade and a single pass of a laser. This may enhance the throughput of manufacturing the semiconductor dies.

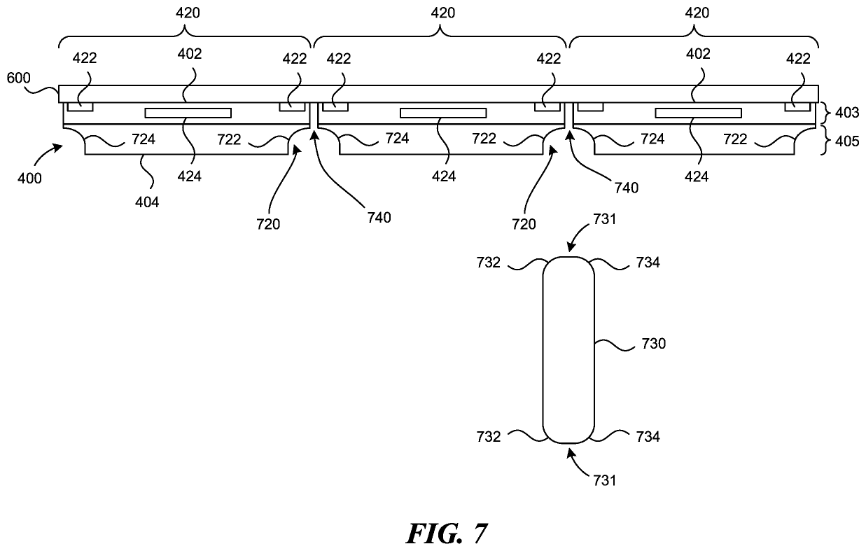

FIG. 7 illustrates an alternative embodiment of the wafer 400 having U-shaped first channels 720 instead of the V-shaped first channels 620 described above. Like reference numbers refer to like components in FIGS. 6A-7. The U-shaped first channels 720 can have first and second sidewalls 722 and 724, respectively, that are defined by first and second curved surfaces. The first channels 720 can be formed by cutting the backside 404 of the wafer 400 to an intermediate depth within the wafer 400 using a saw blade 730 having a cutting edge 731 with first and second curved cutting surfaces 732 and 734, respectively. The cutting surfaces 732 and 734 correspond to the curvatures of the first and second sidewalls 722 and 724, respectively. The process can continue by cutting second channels 740 along the streets in an interface region of the first and second sidewalls 722 and 724 of corresponding first channels 720. As described above, the second channels 740 can be formed by laser cutting along the streets to separate adjacent semiconductor dies 420 from one another. In some embodiments, the second channels 740 are formed by using a dicing blade having cutting surfaces parallel to or within 20°, within 15°, within 10°, and/or within 5° of vertical (e.g., perpendicular to the wafer carrier 600).

The resulting dies 420, of the above-described processes can include overhang portions having varying shapes (e.g., beveled, fileted, or otherwise rabbeted). Examples of these dies are illustrated and described the attached Exhibit A (see, e.g., FIGS. 4-6 and corresponding description). These dies having overhang portions can be vertically stacked while maintaining: (1) a shortened height as compared to dies with spacer tapes; and (2) smaller footprints as compared to shingled die stacks.

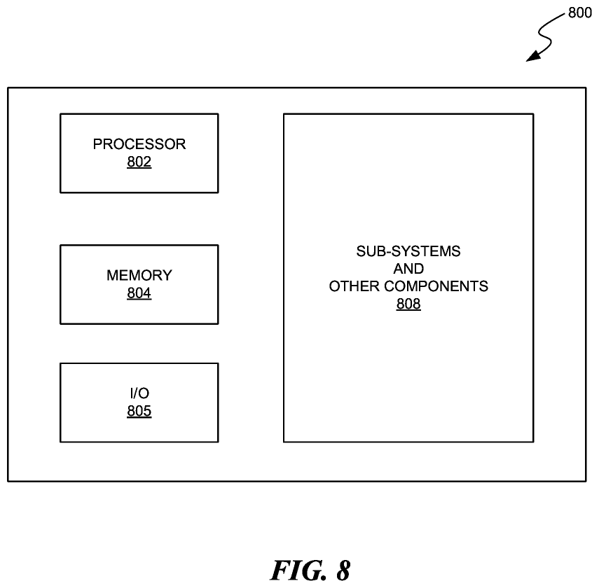

FIG. 8 is a block diagram illustrating a system that incorporates a semiconductor device in accordance with embodiments of the present technology. Any one of the semiconductor devices having the features described above with reference to FIGS. 6A-7 can be incorporated into any of a myriad of larger and/or more complex systems, a representative example of which is system 800 shown schematically in FIG. 8. The system 800 can include a processor 802, a memory 804 (e.g., SRAM, DRAM, flash, and/or other memory devices), input/output devices 806, and/or other subsystems or components 508. The semiconductor assemblies, devices, and device packages described above with reference to FIGS. 6A-7 can be included in any of the elements shown in FIG. 8. The resulting system 800 can be configured to perform any of a wide variety of suitable computing, processing, storage, sensing, imaging, and/or other functions. Accordingly, representative examples of the system 890 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 800 include lights, cameras, vehicles, etc. In these and other examples, the system 800 can be housed in a single unit or distributed over multiple interconnected units, e.g., through a communication network. The components of the system 800 can accordingly include local and/or remote memory storage devices and any of a wide variety of suitable computer-readable media.

Although many of the foregoing embodiments are described with respect to semiconductor devices, systems, and methods with compartmental shielding, other applications and other embodiments in addition to those described herein are within the scope of the present technology. Further, embodiments of the present technology can have different configurations, components, and/or procedures than those shown or described herein, and these and other embodiments can be used without several of the configurations, components, and/or procedures shown or described herein without deviating from the present technology.

As used in the foregoing description, the terms “vertical,” “lateral,” “upper,” and “lower” can refer to relative directions or positions of features in the semiconductor devices in view of the orientation shown in the FIG. s. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, left/right, and distal/proximate can be interchanged depending on the orientation. Moreover, for ease of reference, identical reference numbers are used to identify similar or analogous components or features throughout this disclosure, but the use of the same reference number does not imply that the features should be construed to be identical. Indeed, in many examples described herein, identically numbered features have a plurality of embodiments that are distinct in structure and/or function from each other. Furthermore, the same shading may be used to indicate materials in cross section that can be compositionally similar, but the use of the same shading does not imply that the materials should be construed to be identical unless specifically noted herein.

The foregoing disclosure may also reference quantities and numbers. Unless specifically stated, such quantities and numbers are not to be considered restrictive, but exemplary of the possible quantities or numbers associated with the new technology. Also, in this regard, the present disclosure may use the term “plurality” to reference a quantity or number. In this regard, the term “plurality” is meant to be any number that is more than one, for example, two, three, four, five, etc. For the purposes of the present disclosure, the phrase “at least one of A, B, and C,” for example, means (A), (B), (C), (A and B), (A and C), (B and C), or (A, B, and C), including all further possible permutations when greater than three elements are listed.

From the foregoing, it will be appreciated that specific embodiments of the new technology have been described herein for purposes of illustration, but that various modifications may be made without deviating from the present disclosure. Accordingly, the invention is not limited except as by the appended claims. Furthermore, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the present disclosure. Accordingly, the present disclosure and associated technology can encompass other embodiments not expressly shown or described herein.

I/we claim:

1. A method of forming semiconductor dies with rabbeted regions, the method comprising:
forming a first channel along a street from a backside of the wafer to an intermediate depth between the backside of the wafer and a front side of the wafer, wherein the first channel has a first sloped sidewall and a second sloped sidewall that converge toward each other from the backside toward the intermediate depth; and
forming a second channel by laser cutting from the intermediate depth in the wafer toward the front side of the wafer along an interface region where the first and second sidewalls of the first channel meet thereby separating a set of first semiconductor dies along the first sidewall from a set of second semiconductor dies along the second sidewall, wherein the first sloped sidewall defines a rabbeted region at a side of the first semiconductor dies and the second sloped sidewall defines a rabbeted region at a side of the second semiconductor dies.

2. The method of claim 1 wherein the first and second sidewalls are first and second beveled surfaces, respectively, and forming the first channel comprises cutting the wafer along the street with a saw blade having a beveled cutting edge that shapes the first and second sidewalls.

3. The method of claim 2 wherein the first channel has a V-shape.

4. The method of claim 1 wherein the first and second sidewalls are first and second curved surfaces, respectively, and forming the first channel comprises cutting the wafer along the street with a saw blade having a first curved portion on one side and a second curved portion on an opposing side.

5. The method of claim 4 wherein the first channel has a U-shape.

6. The method of claim 1 wherein forming the second channel comprises cutting from the intermediate depth to the front side of the wafer in a single pass of the laser.

7. The method of claim 1 wherein forming the second channel comprises cutting from the intermediate depth to the front side of the wafer using multiple passes of the laser.

8. The method of claim 1 wherein the first and second channels are formed while the wafer has a first thickness, and the method further comprises thinning the wafer from the backside to a second thickness thinner than the first thickness.

9. The method of claim 1 wherein the front side of the wafer is attached to a carrier material that supports the wafer and protects the front side of the wafer while forming both the first and second channels.

10. The method of claim 1 wherein the second channel has a width of 10-20 μm.

11. The method of claim 1 wherein at least a portion of the first channel has a width greater than a width of the street.

12. A method of forming semiconductors dies with rabbeted regions, the method comprising:
cutting a channel along a street from a backside of a wafer to an intermediate depth between the backside of the wafer and a front side of the wafer, wherein the channel has first and second sloped sidewalls that converge toward each from the backside toward the intermediate depth;
separating first dies along the first sloped sidewall from second dies along the second sloped sidewall by laser cutting along a midline of the channel to form a kerf from the intermediate depth to the front side of the wafer, wherein first sloped sidewall defines a rabbeted region along a side of the first dies and the second sloped sidewall defines a rabbeted region along a side of the second dies.

13. The method of claim 12 wherein the first and second sidewalls are first and second beveled surfaces, respectively, and forming the first channel comprises cutting the wafer along the street with a saw blade having a beveled cutting edge that shapes the first and second sidewalls.

14. The method of claim 13 wherein the first channel has a V-shape.

15. The method of claim 12 wherein the first and second sidewalls are first and second curved surfaces, respectively, and forming the first channel comprises cutting the wafer along the street with a saw blade having a first curved portion on one side and a second curved portion on an opposing side.

16. The method of claim 15 wherein the first channel has a U-shape.

17. The method of claim 12 wherein forming the second channel comprises cutting from the intermediate depth to the front side of the wafer in a single pass of the laser.

18. The method of claim 12 wherein forming the second channel comprises cutting from the intermediate depth to the front side of the wafer using multiple passes of the laser.

19. The method of claim 12 wherein the first and second channels are formed while the wafer has a first thickness, and the method further comprises thinning the wafer from the backside to a second thickness thinner than the first thickness.

20. The method of claim 12 wherein the front side of the wafer is attached to a carrier material that supports the wafer and protects the front side of the wafer while forming both the first and second channels.

21. The method of claim 12 wherein the second channel has a width of 10-20 μm.

22. The method of claim 12 wherein at least a portion of the first channel has a width greater than a width of the street.
